(19) United States
(12) Patent Application Publication
(10) Pub. No.: US 2024/0130087 A1
(43) Pub. Date: Apr. 18, 2024

(54) SLIDE SNAP-FIT STRUCTURE FOR RADIATORS

(71) Applicant: Huizhou Xunshuo Technology Co., Ltd, Huizhou (CN)

(72) Inventors: Zhiliang ZHANG, Huizhou (CN); Zhenzhi LIANG, Huizhou (CN)

(21) Appl. No.: 18/398,066

(22) Filed: Dec. 27, 2023

(30) Foreign Application Priority Data
Oct. 25, 2023 (CN) 202322884719.3

(51) Int. Cl. H05K 7/20

(52) U.S. Cl. CPC H05K 7/20418

(57) ABSTRACT

A slide snap-fit structure for radiators includes a slide snap-fit support assembly, including a first slide support fixed on a side of a fan and a second slide support fixed on a side of a heat-dissipation part. The first slide support is movably connected with the second slide support. By adopting the slide snap-fit structure, the assembly of the fan and the heat-dissipation part can be simplified.

### CROSS-REFERENCE TO RELATED APPLICATIONS

This application claims the benefit of priority from Chinese Patent Application No. 202322884719.3, filed on Oct. 25, 2023. The content of the aforementioned application, including any intervening amendments thereto, is incorporated herein by reference in its entirety.

### TECHNICAL FIELD

This application relates to radiators, and more particularly to a slide snap-fit structure for radiators.

### BACKGROUND

A radiator is used to conduct and release heat, and is usually applied in computer devices, machinery and heating equipment which will produce a lot of heat during the operation. The generated heat can be quickly dissipated through the radiator to avoid accumulation, so as to ensure normal operation of the equipment.

In the prior art, the user needs to install a fan on a dissipation fin by himself, and with respect to the existing radiators on the market, the fan is fixed through steel wire buckles. Considering that the dissipation fin is an aluminum hardware product with sharp corners, it is easy to cause scratches on the users' hands when fixing the fan through the steel wire buckles. In order to overcome the problems of complicated installation and operation and potential safety hazard, and enable the safe and simple installation of the fan on the dissipate fin, a quick-assembly structure is needed.

### SUMMARY

An object of this application is to provide a slide snap-fit structure for radiators to overcome the shortcomings of the prior art.

Technical solutions of the present disclosure are described as follows.

The present disclosure provides a slide snap-fit structure for radiators, comprising: a slide snap-fit support assembly; wherein the slide snap-fit support assembly comprises a first slide support and a second slide support; the slide snap-fit support assembly can be assembled simply and safely; a structure of the first slide support and the second slide support is simple and easy to process; the first slide support is fixed on a side of a fan; the second slide support is fixed on a side of a heat-dissipation part; the first slide support is movably connected with the second slide support; and the first slide support is inserted into an interior of the second slide support from above to complete the assembly during using.

In an embodiment, a side of the first slide support facing toward the second slide support is provided with a T-shaped protrusion; a side of the second slide support facing toward the first slide support is provided with a T-shaped groove, and the T-shape groove can accommodate the T-shaped protrusion; a transverse displacement of the T-shaped protrusion is limited when is located in the T-shaped groove; the T-shaped protrusion is configured to enter an interior of the T-shaped groove through a top of the T-shaped groove, so as to realize a fixed way which can only move up and down; the side of the first slide support facing toward the second slide support is provided with a limit protrusion; the limit protrusion is arranged on a tail section of the T-shaped protrusion, which ensures that the first slide support will not pass through the second slide support; the limit protrusion is configured to fail to enter the interior of the T-shaped groove; and the limit protrusion is higher than the T-shaped groove, so as to limit a downward sliding distance of the first slide support.

In an embodiment, the slide snap-fit support assembly is arranged between the fan and the heat-dissipation part, and the fan is movably connected with the heat-dissipation part through the slide snap-fit support assembly.

In an embodiment, the heat-dissipation part includes a heat conducting pipe, a heat-dissipation fin and a heat-dissipation base; the heat-dissipation base is located at a bottom of the heat conducting pipe; the heat-dissipation base is arranged on a heat source and is configured to conduct heat to the heat conducting pipe; the heat-dissipation fin is arranged on the heat conducting pipe; the heat conducting pipe is configured to conduct heat to the heat-dissipation fin, and a heat dissipation area is increased through the heat-dissipation fin with a thin-slice structure to rapidly dissipate heat; the heat-dissipation fin is provided with a first fixing hole configured for the second slide support; and the first fixing hole is configured to fix the second slide support.

In an embodiment, the second slide support has a concave-shaped structure formed by a rectangle bottom and two extension portions respectively arranged at two ends of the rectangular bottom; the two extension portions are located at the same side of the rectangular bottom; the two extension portions of the second slide support are each provided with a second fixing hole configured for fixing the second slide support; the slide snap-fit structure further comprises a first fixing screw, and the first fixing screw is configured to run through the first fixing hole and the second fixing hole to fix the second slide support; and the second fixing hole cooperates with the first fixing hole to fix the second slide support on the heat-dissipation part.

In an embodiment, a back of the fan is provided with a first fixing hole; two ends of the first slide support are each provided with a second fixing hole; the slide snap-fit structure further comprises a second fixing screw, and the second fixing screw is configured to run through the first fixing hole and the second fixing hole to fix the first slide support; and the first fixing hole cooperates with the second fixing hole to fix the first slide support on the fan.

In an embodiment, the heat conducting pipe is perpendicularly inserted into a through hole of the heat-dissipation fin in an interference fit manner; and the heat conducting pipe is configured to conduct heat to the heat-dissipation fin.

In an embodiment, the second slide support is provided with at least one heat-dissipation hole; and the at least one heat-dissipation hole is configured to ensure ventilation of the second slide support and prevent a decrease of heat dissipation efficiency of the second slide support.

In an embodiment, the number of the slide snap-fit support assembly is two; two slide snap-fit support assemblies are arranged between the fan and the heat-dissipation part; and the two slide snap-fit support assemblies are configured to fix the fan on the heat-dissipation part better.

The present disclosure has the following beneficial effects.

In the present disclosure, the heat-dissipation part includes a heat-dissipation fin and a heat conducting pipe, which can effectively transfer the heat to a surface of the heat-dissipation fin and increase the heat dissipation surface area, so as to improve the heat dissipation efficiency. The slide snap-fit support assembly is arranged between the fan and the heat-dissipation part, which can be assembled simply and safely. The slide snap-fit support assembly includes a first slide support fixed on a side of the fan and a second slide support fixed on a side of the heat-dissipation part. The first slide support is fixedly connected with the fan, and the second slide support is fixedly connected with the heat-dissipation part. The first slide support is movably connected with the second slide support. In the actual use, the first slide support is inserted into the interior of the second slide support from above to complete the assembly. When installing the fan, it only needs to align the first slide support with the second slide support, and then vertically insert the first slide support into the second slide support to fix the fan, which can not only simplify the assembly operation, but also prevent users' hands from being scratched, allowing for convenient use and high safety. In addition, the present disclosure has advantages of quick disassembly and assembly and simple structure.

### BRIEF DESCRIPTION OF THE DRAWINGS

In order to describe the technical solutions of embodiments of the present disclosure more clearly, the drawings needed in the description of the embodiments will be briefly introduced below. It can be understood that the accompanying drawings herein only show some embodiments of this application, rather than limiting this application. It should be noted that those skilled in the art can also obtain other accompanying drawings according to the accompanying drawings provided herein without making creative effort.

FIG. 1 shows a slide snap-fit structure for radiators according to an embodiment of the present disclosure in a use state;

FIG. 2 is an exploded view of the slide snap-fit structure according to an embodiment of the present disclosure;

FIG. 3 is another exploded view of the slide snap-fit structure according to an embodiment of the present disclosure;

FIG. 4 is a sectional view of a slide snap-fit support assembly according to an embodiment of the present disclosure;

FIG. 5 is a perspective view of a first slide support according to an embodiment of the present disclosure;

FIG. 6 is a perspective view of a second slide support according to an embodiment of the present disclosure;

FIG. 7 is another perspective view of the second slide support according to an embodiment of the present disclosure;

FIG. 8 is another perspective view of the first slide support according to an embodiment of the present disclosure;

FIG. 9 is a perspective view of a heat-dissipation part according to an embodiment of the present disclosure;

FIG. 10 is a perspective view of a fan according to an embodiment of the present disclosure;

FIG. 11 is a front view of the slide snap-fit structure according to an embodiment of the present disclosure;

FIG. 12 is a top view of the slide snap-fit structure according to an embodiment of the present disclosure;

FIG. 13 is a perspective view of the slide snap-fit structure according to an embodiment of the present disclosure.

In the figures: fan 1, heat-dissipation part 2, slide snap-fit support assembly 3, first slide support 4, second slide support 5, T-shaped protrusion 6, T-shaped groove 7, limit protrusion 8, heat conducting pipe 9, heat-dissipation fin 10, heat-dissipation base 11, first fixing hole 12, second fixing hole 13, first fixing screw 14, third fixing hole 15, fourth fixing hole 16, second fixing screw 17, and heat-dissipation hole 18.

### DETAILED DESCRIPTION OF EMBODIMENTS

The present disclosure will be further described below with reference to the accompanying drawings and embodiments. It can be understood that the embodiments described herein are only to illustrate this application rather than limiting this application. On the contrary, the embodiments are provided for the purpose of a more thorough and comprehensive understanding of the present disclosure.

In the description of this embodiment, if a component is said to be “fixed” to another component, it can be directly fixed to another component or indirectly fixed to another component through an intermediate component. If a component is said to be “connected” to another component, it can be directly connected to another component or indirectly connected to another component through an intermediate component. Terms, such as “vertical”, “horizontal”, “left” and “right”, are only to illustrate this application rather than limiting the implementation of this application.

Unless otherwise defined, all technical and scientific terms used herein have the same meaning as commonly understood by those skilled in the art. These terms are only descriptive, and are not intended to limit the application. The term “and/or” used herein includes any and all combinations of one or more relevant listed items.

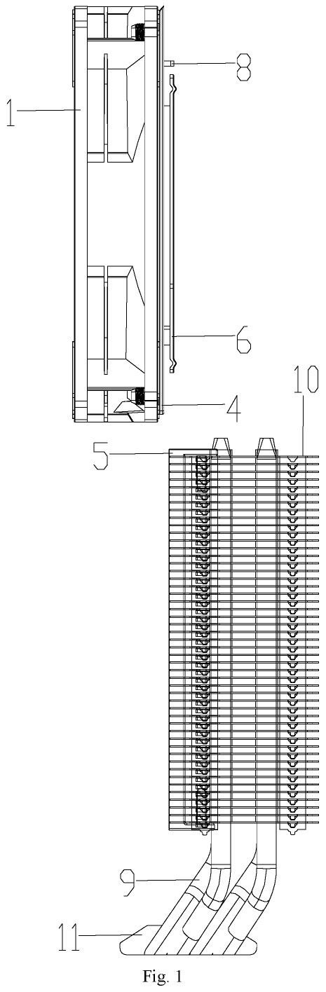

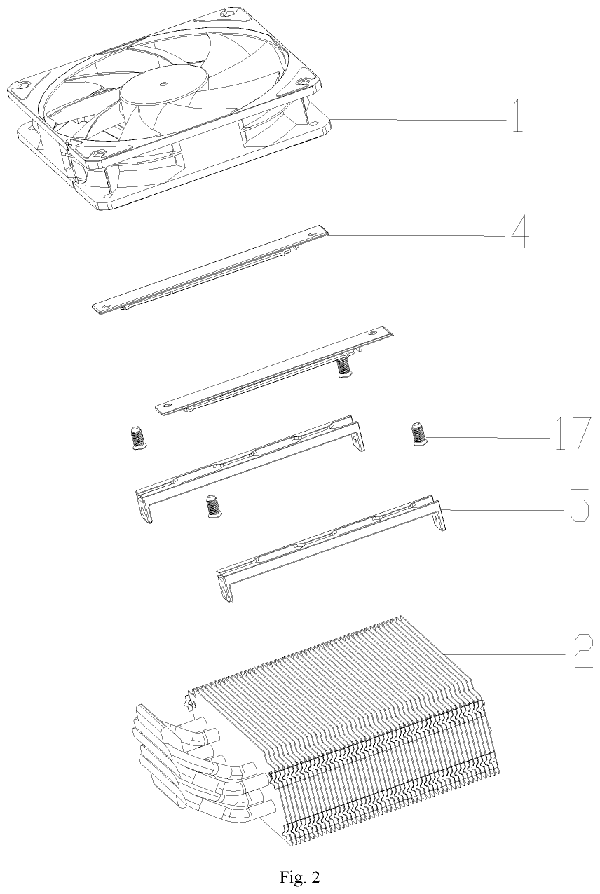

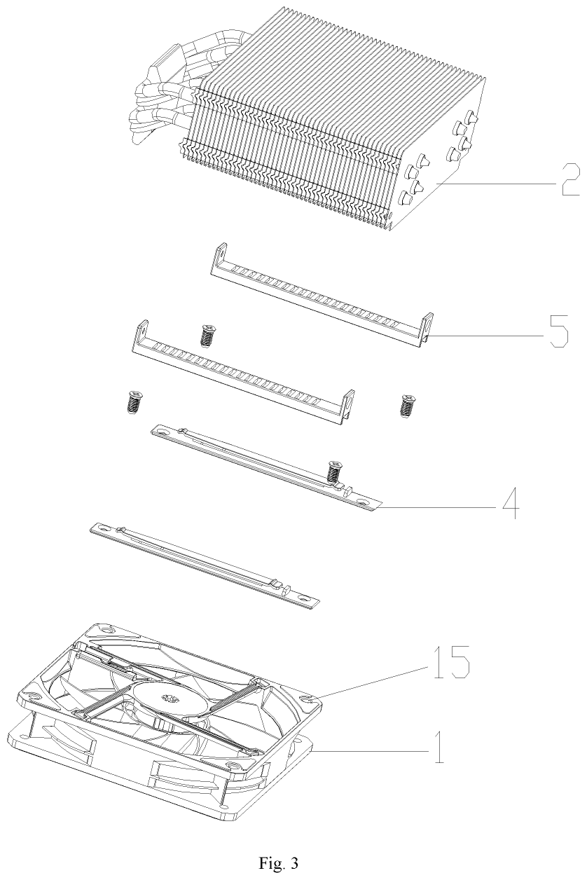

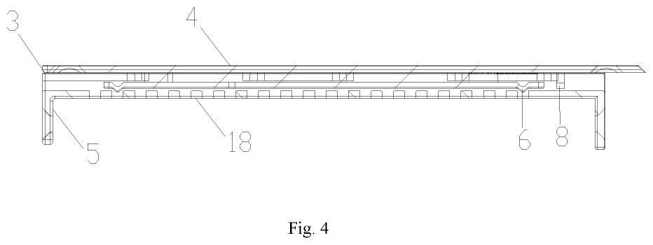

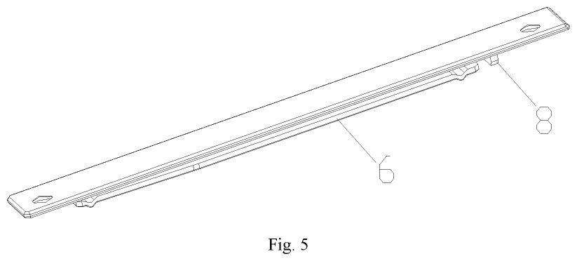

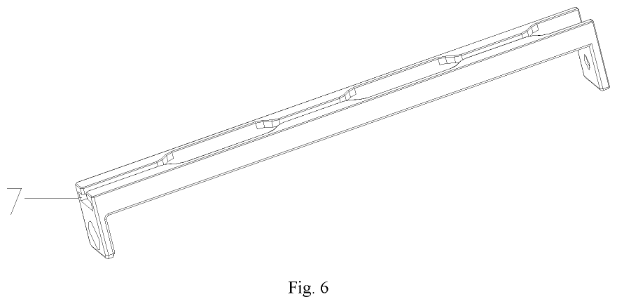

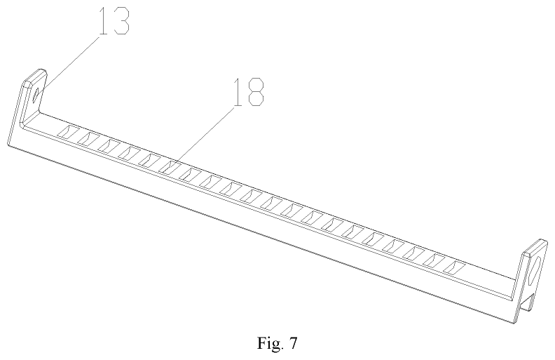

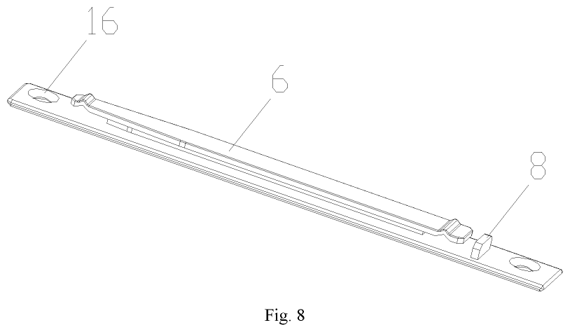

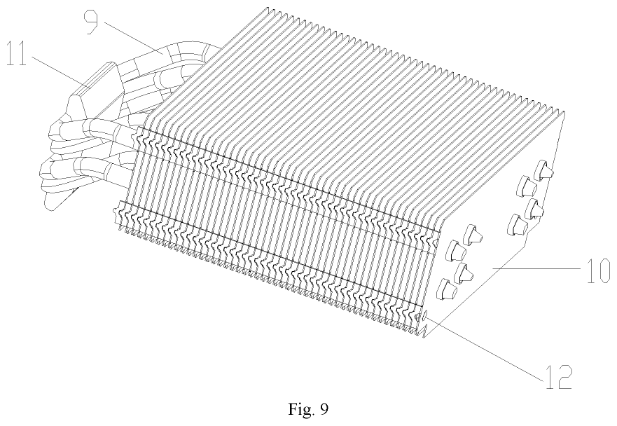

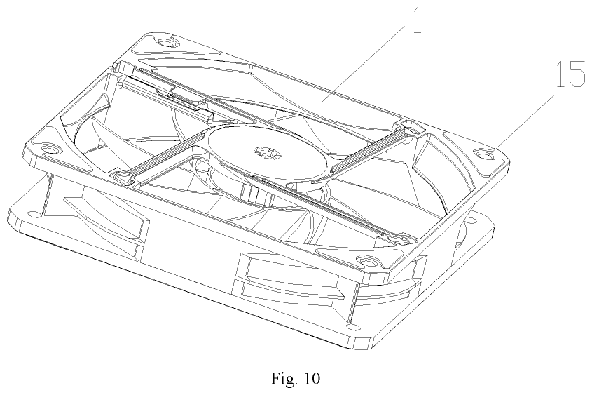

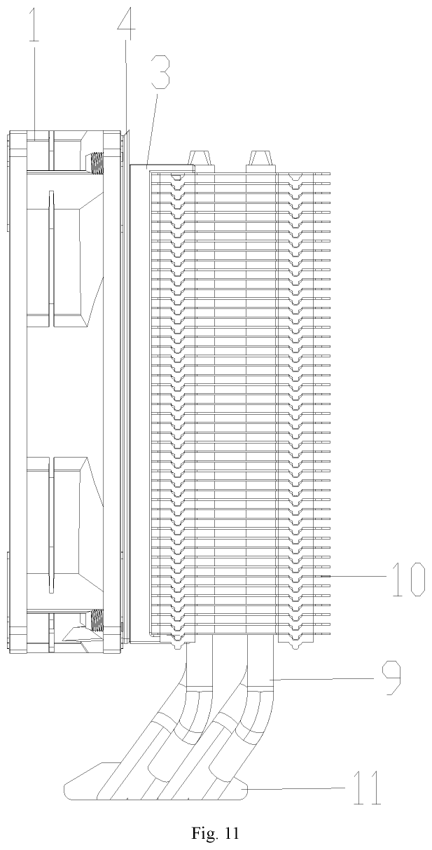

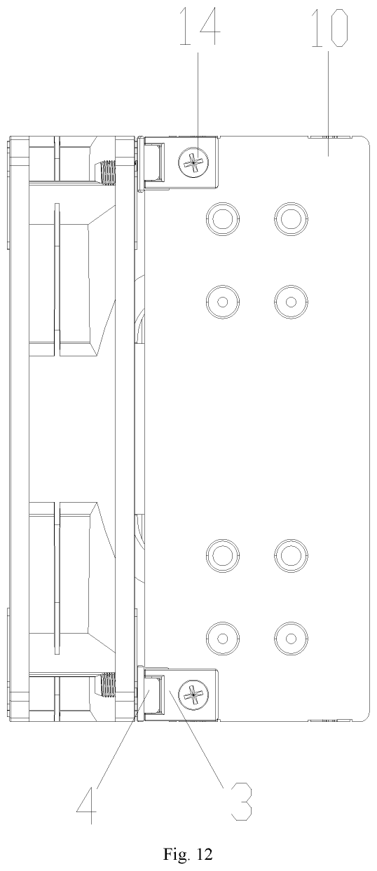

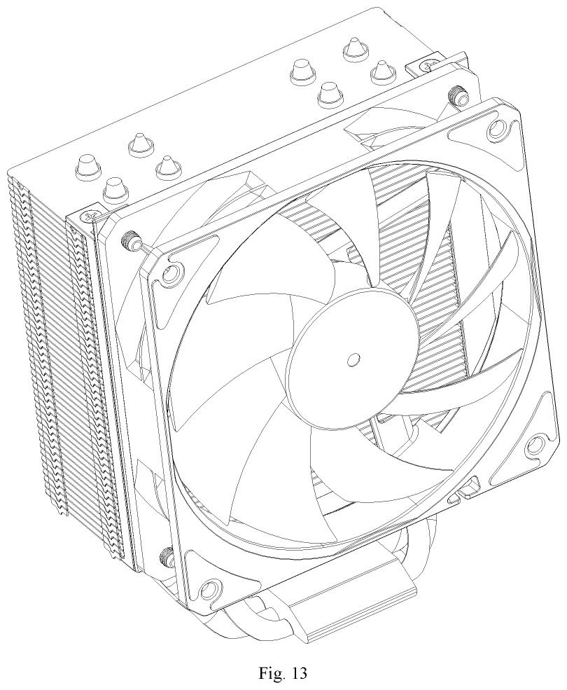

An embodiment shown in FIGS. 1-13 provides a slide snap-fit structure for radiators, including a slide snap-fit support assembly 3. The slide snap-fit support assembly 3 includes a first slide support 4 and a second slide support 5; the first slide support 4 is fixed on a side of a fan 1; the second slide support 5 is fixed on a side of a heat-dissipation part 2; and the first slide support 4 is movably connected with the second slide support 5.

By adopting the above technical solutions, the slide snap-fit support assembly 3 is arranged between the fan 1 and the heat-dissipation part 2. The heat-dissipation part 2 cooperates with the fan 1 to realize the quick heat dissipation. A heat conducting pipe 9 of the heat-dissipation part 2 is configured to conduct heat to a surface of a heat-dissipation fin 10 of the heat-dissipation part 2, which increase the surface area for heat dissipation, so as to increase heat dissipation efficiency. An arrangement and operation of the slide snap-fit support assembly 3 between the fan 1 and the heat-dissipation part 2 are easy and safe. The slide snap-fit support assembly 3 includes a first slide support 4 and a second slide support 5. The first slide support 4 is fixed on a side of the fan 1, and the second slide support 5 is fixed on a side of the heat-dissipation part 2. The first slide support 4 is connected with the second slide support 5 through sliding up and down. In an actual use, the first slide support 4 is inserted into an interior of the second slide support 5 from above to complete an assembly of the heat-dissipation part 2.

In an embodiment, a side of the first slide support 4 facing toward the second slide support 5 is provided with a T-shaped protrusion 6. A side of the second slide support 5 facing toward the first slide support 4 is provided with a T-shaped groove 7. The T-shaped protrusion 6 is configured to enter an interior of the T-shaped groove 7 through a top of the T-shaped groove 7. The side of the first slide support 4 facing toward the second slide support 5 is provided with a limit protrusion 8. The limit protrusion 8 is arranged on a tail section of the T-shaped protrusion 6. And the limit protrusion 8 is configured to fail to enter the interior of the T-shaped groove 7.

By adopting the above technical solution, a transverse displacement of the fan 1 is limited when the T-shaped protrusion 6 of the side of the first slide support 4 facing toward the second slide support 5 is located in the T-shaped groove 7 for fixing the fan 1. A shape of the T-shaped groove 7 of the side of the second slide support 5 facing toward the first slide support 4 is configured to match with a shape of the T-shaped protrusion 6. The T-shaped protrusion 6 is configured to enter the interior of the T-shaped groove 7 through a top of the T-shaped groove 7, so as to realize a fixed way that can only move up and down. The limit protrusion 8 of the side of the first slide support 4 facing toward the second slide support 5 is arranged on the tail section of the T-shaped protrusion 6. The limit protrusion 8 is configured to fail to enter the interior of the T-shaped groove and is configured to ensure that the first slide support 4 will not penetrate the second slide support 5. The limit protrusion 8 is higher than the a I-shaped groove of T-shaped groove, so as to limit a downward sliding distance of the first slide support 4.

In an embodiment, the heat-dissipation part 2 includes the heat conducting pipe 9, a heat-dissipation fin 10 and a heat-dissipation base 11. The heat-dissipation base 11 is located at a bottom of the heat conducting pipe 9. The heat-dissipation fin 10 is arranged on the heat conducting pipe 9. The heat-dissipation fin 10 is provided with a first fixing hole 12.

By adopting the above technical solution, the heat-dissipation base 11 located at the bottom of the heat conducting pipe 9 is arranged on a heat source and is configured to conduct heat to the heat conducting pipe 9. The heat conducting pipe 9 is configured to conduct heat to the heat-dissipation fin 10, and a heat dissipation area is increased through the heat-dissipation fin 10 with a thin-slice structure to rapidly dissipate heat. The heat-dissipation fin 10 is provided with a first fixing hole 12 configured for fixing the second slide support 5.

In an embodiment, the second slide support 5 has a concave-shaped structure formed by a rectangular bottom and two extension portions respectively arranged at two ends of the rectangular bottom; the two extension portions are located at the same side of the rectangular bottom. The two extension portions of the second slide support 5 are each provided with a second fixing hole 13. The slide snap-fit structure further comprises a first fixing screw 14, and the first fixing screw 14 is configured to run through the first fixing hole 12 and the second fixing hole 13 to fix the second slide support 14.

By adopting the above technical solution, the second slide support 5 is just in snap-fit on the heat-dissipation part 2. The first fixing screw 14 is configured to run through the first fixing hole 12 and the second fixing hole 13 to fix the second slide support 14, so as to fix the second slide support 5 on the heat-dissipation part 2.

In an embodiment, a back of the fan 1 is provided with a third fixing hole 15. Two ends of the first slide support 4 are each provided with a fourth fixing hole 16. The slide snap-fit structure further comprises a second fixing screw 17, and the second fixing screw 17 is configured to run through the third fixing hole 15 and the fourth fixing 16.

By adopting the above technical solution, the second fixing screw 17 is configured to run through the third fixing hole 15 and the fourth fixing 16, so as to realize a function that the first slide support 4 is fixed on the fan 1.

In an embodiment, the heat conducting pipe 9 is perpendicularly inserted into a through hole of the heat-dissipation fin 10 in an interference fit manner.

By adopting the above technical solution, the heat conducting pipe 9, which is perpendicularly inserted into a through hole of the heat-dissipation fin 10, is configured to conduct heat to the heat-dissipation fin 10.

In an embodiment, the second slide support 5 is provided with at least one heat-dissipation hole 18.

By adopting the above technical solution, the at least one heat-dissipation hole 18 on the second slide support 5 is configured to ensure ventilation of the second slide support 5 and prevent a decrease of heat dissipation efficiency of the second slide support 5.

In an embodiment, the number of the slide snap-fit support assembly 3 is two, and two slide snap-fit support assemblies 3 are arranged between the fan 1 and the heat-dissipation part 2.

By adopting the above technical solution, the two slide snap-fit support assemblies 3 are arranged between the fan 1 and the heat-dissipation part 2, and the two slide snap-fit support assemblies 3 are configured to fix the fan 1 on the heat-dissipation part 2 better.

The working principle of this application is described as follows. Through the cooperation of the T-shaped protrusion 6 of the first slide support 4, the T-shaped groove 7 of the second slide support 5 and the limit protrusion 8 of the first slide support 4, the movable snap-fit of the fan 1 and the heat-dissipation part 2 along the vertical direction is realized.

When installing, the first slide support 4 is inserted downward into the interior of the second slide support 5, and then the radiator with the fan 1 stably fixed is arranged on a position where the heat dissipation is needed to complete the installation.

Described above are only several embodiments of the present disclosure, and are not intended to limit the disclosure. It should be noted that any modifications or improvements made by those skilled in the art without departing from the scope of the present disclosure shall fall within the scope of the present disclosure defined by the appended claims.

What is claimed is:

1. A slide snap-fit structure for radiators, comprising:
a slide snap-fit support assembly;
wherein the slide snap-fit support assembly comprises a first slide support and a second slide support; the first slide support is fixed on a side of a fan; the second slide support is fixed on a side of a heat-dissipation part; and the first slide support is movably connected with the second slide support.

2. The slide snap-fit structure of claim 1, wherein a side of the first slide support facing toward the second slide support is provided with a T-shaped protrusion; a side of the second slide support facing toward the first slide support is provided with a T-shaped groove; the T-shaped protrusion is configured to enter an interior of the T-shaped groove through a top of the T-shaped groove; the side of the first slide support facing toward the second slide support is provided with a limit protrusion; and the limit protrusion is arranged on a tail section of the T-shaped protrusion; and the limit protrusion is configured to fail to enter the interior of the T-shaped groove.

3. The slide snap-fit structure of claim 1, wherein the slide snap-fit support assembly is arranged between the fan and the heat-dissipation part.

4. The slide snap-fit structure of claim 1, wherein the heat-dissipation part comprises a heat conducting pipe, a heat-dissipation fin and a heat-dissipation base; the heat-dissipation base is located at a bottom of the heat conducting pipe; the heat-dissipation fin is arranged on the heat conducting pipe; and the heat-dissipation fin is provided with a first fixing hole configured for fixing the second slide support.

5. The slide snap-fit structure of claim 4, wherein the second slide support has a concave-shaped structure formed by a rectangular bottom and two extension portions respectively arranged at two ends of the rectangular bottom; the two extension portions are located at the same side of the rectangular bottom; the two extension portions of the second slide support are each provided with a second fixing hole configured for fixing the second slide support; the slide snap-fit structure further comprises a fixing screw, and the fixing screw is configured to run through the first fixing hole and the second fixing hole to fix the second slide support.

6. The slide snap-fit structure of claim 1, wherein a back of the fan is provided with a first fixing hole configured for fixing the first slide support; two ends of the first slide support are each provided with a second fixing hole; the slide snap-fit structure further comprises a fixing screw, and the fixing screw is configured to run through the first fixing hole and the second fixing hole to fix the first slide support.

7. The slide snap-fit structure of claim 4, wherein the heat conducting pipe is perpendicularly inserted into a through hole of the heat-dissipation fin in an interference fit manner.

8. The slide snap-fit structure of claim 1, wherein the second slide support is provided with at least one heat-dissipation hole.

9. The slide snap-fit structure of claim 1, wherein the number of the slide snap-fit support assembly is at least one, and at least one slide snap-fit support assembly is arranged between the fan and the heat-dissipation part.
